(19) United States
(12) Patent Application Publication
(10) Pub. No.: US 2019/0013785 A1
(43) Pub. Date: Jan. 10, 2019

(54) ACOUSTIC ELEVATOR COMMUNICATION SYSTEM AND METHOD OF ADJUSTING SUCH A SYSTEM

(71) Applicant: Otis Elevator Company, Farmington, CT (US)

(72) Inventor: Craig D. Bogli, Avon, CT (US)

(21) Appl. No.: 16/066,419

(22) PCT Filed: Dec. 29, 2015
(86) PCT No.: PCT/IB2015/002427

§ 371 Date: Jun. 27, 2018

(51) Int. Cl. H03G 3/30; H04R 1/08; H03G 5/00; H03G 5/16; B66B 1/34

(52) U.S. Cl. CPC H03G 3/301; H04R 1/08; H03G 3/3089; H04R 2499/13; H03G 5/165; B66B 1/3446; H03G 5/005

(57) ABSTRACT

An acoustic elevator communication system (1) comprises a speaker (4) on an output line (6) and a microphone (8) on an input line (10), the speaker (4) and the microphone (8) being installed inside an elevator car (2); a sound generator (24) connected with the output line (6); and an adjustment unit (25). The adjustment unit (25) is configured for (A1) driving the sound generator (24) for delivering a first speaker signal to the speaker (4), the first speaker signal in particular being a white noise signal causing the speaker (4) to produce white noise sound; (B1) receiving the sound generated by the speaker (4) with the microphone (8) generating a first microphone signal; (C1) determining acoustic resonances from the first microphone signal; (D1) adjusting the speaker signal such as to eliminate the acoustic resonances in the first microphone signal.

Today's elevator installations are usually provided with acoustic elevator communication systems for allowing passengers residing within an elevator car to communicate with service personnel, for example service personnel of a service center, in particular in emergency situations; e.g. when the elevator system is not working properly and the passengers are trapped within the elevator car.

The acoustics of the elevator cars may vary significantly from installation to installation, e.g. due to the type of materials used to cover the cab walls, floors, and ceiling, as well as the location of the speaker and the microphone within the elevator car. Thus, in order to ensure a good quality of the acoustic communication, each acoustic elevator communication system needs to be adjusted to the specific installation.

Due to a large number of adjustable parameters, the adjustment process, however, is cumbersome and the person doing the adjustment needs a lot of experience to be able to achieve good results.

Therefore, it would be beneficial to optimize and facilitate said adjustment process.

According to an exemplary embodiment of the invention, an acoustic elevator communication system comprises a speaker on an input line and a microphone on an output line, the speaker and the microphone being installed inside the elevator car; a sound generator connected with the input line; and an adjustment unit. The acoustic elevator communication system is configured for
(A1) driving the sound generator for delivering a first speaker signal to the speaker, the first speaker signal in particular being a white noise signal causing the speaker to produce white noise sound;
(B1) receiving the sound generated by the speaker with the microphone generating a first microphone signal;
(C1) determining acoustic resonances from the first microphone signal; and
(D1) adjusting the speaker signal such as to eliminate the acoustic resonances in the first microphone signal.

According to an exemplary embodiment of the invention, a method of adjusting an acoustic elevator communication system, which comprises a speaker on an input line and a microphone on an output line, the speaker and the microphone being installed within an elevator car, comprises the steps of:
(a1) delivering a first speaker signal to the speaker, the first speaker signal in particular being a white noise signal causing the speaker to produce white noise sound;
(b1) receiving the sound generated by the speaker with the microphone generating a first microphone signal;
(c1) determining acoustic resonances from the first microphone signal; and
(d1) adjusting the speaker signal such as to eliminate the acoustic resonances in the first microphone signal.

According to exemplary embodiments of the invention, acoustic resonances occurring in an acoustic elevator communication system are eliminated. The methods according to exemplary embodiments of the invention in particular may be executed automatically, i.e. without human intervention apart from starting the method to be executed.

Exemplary embodiments of the invention considerably facilitate the adjustment process. They further eliminate the subjectivity and therefore result in a more consistent transmission quality. The risk of misadjusting the acoustic elevator communication system to a point where acoustic communication is not possible is reliably avoided and the time required for calibrating and testing the acoustic elevator communication system is considerably reduced.

Exemplary embodiments of the invention will be described in more detail in the following with reference to the enclosed figures:

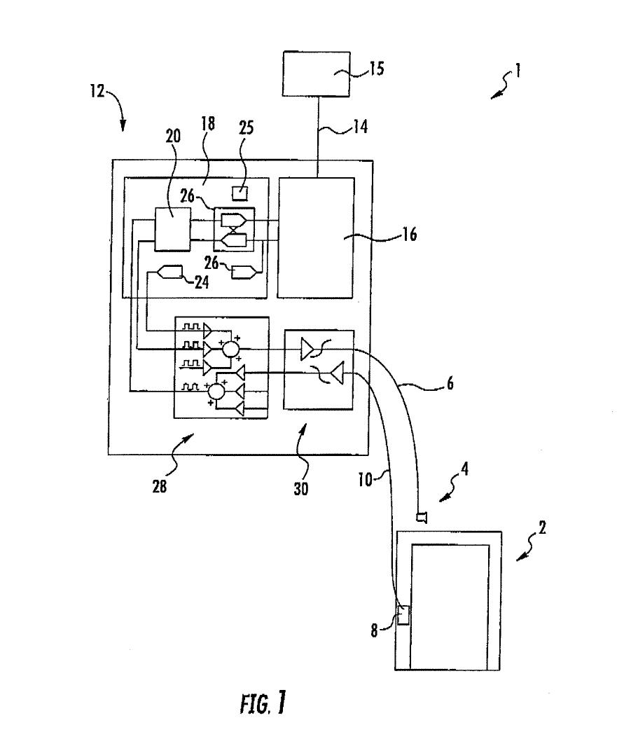

FIG. 1 depicts a schematic view of acoustic elevator communication system according to an exemplary embodiment of the invention.

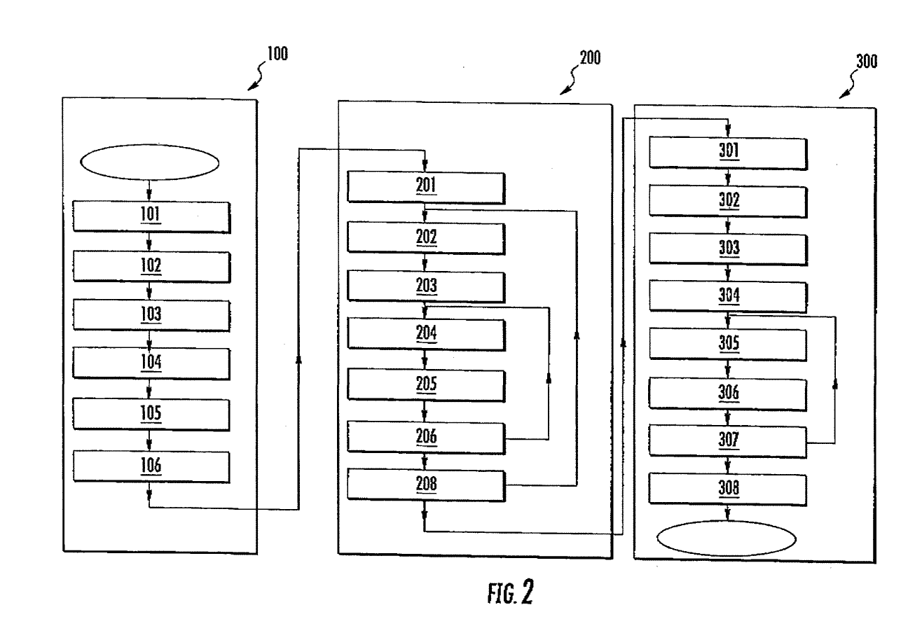

FIG. 2 depicts a flow chart illustrating a method of adjusting an acoustic elevator communication system according to an exemplary embodiment of the invention.

FIG. 1 shows a schematic view of acoustic elevator communication system 1 according to an exemplary embodiment of the invention.

An elevator system comprises at least one elevator car 2, which is configured for traveling along a hoistway (not shown) between a plurality of landings (not shown). The skilled person will understand that exemplary embodiments of the invention may be adjusted easily to be employed with elevator systems comprising a plurality of elevator cars 2.

The acoustic elevator communication system 1 comprises a speaker 4 and a microphone 8, which are installed within the elevator car 2. The skilled person will understand that exemplary embodiments of the invention may be adjusted to be applied to acoustic elevator communication systems 1 comprising a plurality of speakers 4 and/or a plurality of microphones 8 easily by simple, straightforward modifications.

The acoustic elevator communication system 1 further comprises a communication unit 12, which is configured for establishing communication between passengers (not shown) residing within the elevator car 2 and the personnel of an external service center 15. The communication unit 12 in particular is configured for establishing communication links, between the speaker 2 and the microphone 4 installed within an elevator car 2 with the external service center 15 via an analog or digital line 14. Said line 14 may include a conventional telephone line, a digital wire or fiber line and/or a wireless data connection.

The speaker 2 is connected to the communication unit 12 by means of an output line 6, and the microphone 8 is connected to the communication unit 12 by means of an input line 10.

The communication unit 12 comprises a modem signal processing unit 16, an audio signal processing unit 18, a codec unit 28, and an analog gain adjustment unit 30.

For the purpose of the following description, these units 16, 18, 28, 30 are depicted as individual functional units in FIG. 1. The skilled person, however, easily understands that some or all of these functional units may be integrated with each other. Their functions in particular may be provided by a single signal processor, such as the “ADSP-21065L Digital Signal Processor” from the DSP Applications Group, Analog Devices, Norwood, Mass. 02062, USA. The signal processor may be configured for providing the required functionalities by running appropriate software.

The output line 6 and the input line 10 respectively connect the speaker 4 and the microphone 8 with the analog gain adjustment unit 30, which allows for an analog adjustment of the signals received from the microphone 8 and of the signals supplied to the speaker 4.

The analog gain adjustment unit 30 is functionally connected with the codec unit 28, which is configured for digitally adjusting the signals. This in particular includes mixing and amplifying the signals. The codec unit 28 further may be configured for playing pre-recorded messages to the passengers residing within the elevator car 2, for example while the connection to the service center 15 is established and/or when the connection to the service center 15 is interrupted and/or cannot be (re-)established.

The codec unit 28 is functionally connected with the audio signal processing unit 18, which comprises an equalizer 20, in particular a bi-directional equalizer 20, an echo canceler 22, an adjustment unit 25 and two sound generators 24, 26. The equalizer in particular is a bi-directional equalizer 20, having a first channel, which is configured for adjusting the speaker signal, and a second channel, which is configured for adjusting the microphone signal.

The functionality of the audio signal processing unit 18 will be described in more detail further below with reference to FIG. 2.

The audio signal processing unit 18 finally is functionally connected with the modem signal processing unit 16 which is configured for establishing a connection with the service center 15 via the analog or digital line 14.

FIG. 2 is a flow chart illustrating a method of adjusting an acoustic elevator communication system according to an exemplary embodiment of the invention.

The method basically comprises three fundamental sections 100, 200, 300, which are executed consecutively and/or individually and which are respectively related to different aspects of adjusting parameters of the acoustic elevator communication system 1.

The first section 100 is related to the task of eliminating acoustic resonances which may occur within the elevator car 2.

In a first (initialization) step 101 the characteristics of the equalizer 20 is set flat in both channels so that the frequency spectrum of the signals is not modified when passing the equalizer 20.

In a second step 102 the first sound generator 24 is driven by the adjustment unit 25 for generating a first speaker signal, in particular a white noise signal, which is supplied to the speaker 4 via the codec unit 28, the analog adjustment gain unit 30 and the output line 6 (step 103). As a result, the speaker 4 generates a corresponding sound within the elevator car 2.

In step 104 the sound, which has been generated by the speaker 4, is received by the microphone 8 generating a corresponding first microphone signal. Said first microphone signal is supplied via the input line 10, the analog adjustment gain unit 30, and the codec unit 28 to the audio signal processing unit 18. In the audio signal processing unit 18, the first microphone signal is analyzed by the adjustment unit 25 for identifying acoustic resonances within the elevator car 2, in particular by locating frequency peaks in the first microphone signal (step 105).

In the following step 106 the characteristics of the channels of the equalizer 20 are adjusted appropriately, i.e. basically corresponding to the inverse of the resonances, for attenuating the identified frequency peaks. This adjustment compensates for the acoustic resonances within the elevator car 2.

As a result, at the end of the first section 100, a basically resonance free acoustic communication between the service center 15 and the elevator car 2 is established.

The second section 200 is related to the task of adjusting the volume of the sound generated by the speaker 4 to an optimal, or at least almost optimal, level.

As a starting point, the speaker gain is set to its maximum level, and the microphone gain is set to a moderate/intermediate level (step 201).

In a next step 202 the first sound generator 24 is set to a predetermined frequency in the range of 100 Hz to 5000 Hz, a second speaker signal, which is a tone signal having the set frequency, is supplied from the first sound generator 24 to the speaker 4 (step 203).

Again, the sound generated by the speaker 4 is received by the microphone 8, generating a corresponding second microphone signal (step 204). Said second microphone signal is analyzed by the adjustment unit 25 for identifying distortions of the tone (step 205). In case any distortions are detected and/or the detected distortions exceed a predetermined lower limit (206), the speaker gain is reduced by a predetermined amount and the procedure is repeated (step 207) until no distortions exceeding the predetermined lower limit are detected. When no such distortions are detected anymore, the procedure is repeated (step 208) for a plurality of different frequencies in the typical audible range, in particular in the range of 100 Hz to 5000 Hz, until not distortions are detected for any of the different frequencies.

As a result, at the end of the second section 200, the gain of the speaker 4 is set to or at least close to the maximum value which is possible without causing distortions of the speaker signal.

The third section 300 is related to the task of ensuring that acoustic messages may be transmitted from the service center 15 into the elevator car 2 under all operational circumstances.

In order to enhance the quality of the acoustic transmission, the exemplary embodiment of an acoustic elevator communication system 1 shown in FIG. 1 comprises an echo canceler 22, which is configured to avoid that acoustic echos and feedback are generated by the acoustic elevator communication system 1.

However, when misconfigured, the echo canceler 22 might cancel also acoustic messages which are to be delivered into the elevator car 2, in particular in situations in which the personnel within the service center 15 and passengers within the elevator car 2 speak simultaneously. Such a situation is to be avoided. For safety reasons the personnel within the service center 15 needs to be able to deliver acoustic messages into the elevator car 2 any time.

For adjusting the echo canceler 22 appropriately, a second sound generator 26 is provided within the audio signal processing unit 18 (see FIG. 1). The second sound generator 26 is connected to the signal path leading to the speaker 4 upstream of the echo canceler 22, i.e. the signals generated by the second sound generator 26 pass the echo canceler 22 before being supplied to the speaker 4 via the equalizer 29, the codec unit 28 and the analog gain adjustment unit 30. Thus, the signals generated by the second sound generator 26 simulate signals which have been received from the external service center 15 via the analog or digital line 14.

In step 301 (see FIG. 2) the second sound generator 26 is triggered by the adjustment unit 25 for generating an appropriate third speaker signal, in particular a white noise signal.

The level settings of the sound generator 26 are set to be equivalent to the levels of signals which have been received via the analog or digital line 14 from the external service center 15 (step 302).

The third speaker signal is supplied to the upstream input side of the echo canceler 22 to be supplied to the speaker 4 via the echo canceler 22, the equalizer 29, the codec unit 28 and the analog gain adjustment unit 30 (step 303).

Simultaneously, the first sound generator 24 is driven to generate at least one fourth speaker signal, which is supplied to the input side of the codec unit 28 for being supplied to the speaker 4 via the analog gain adjustment unit 30 as well (step 304). It is noted that the fourth speaker signal bypasses the echo canceler 22.

The fourth speaker signal in particular comprises a tone signal or a series of tone signals, each of the tone signals respectively including a characteristic frequency.

The sound, which is generated by the speaker 4 as a result of being supplied simultaneously with the third and fourth speaker signals, is picked up by the microphone generating a corresponding third microphone signal (step 305).

In step 306, said third microphone signal is supplied via the input line 10, the analog gain adjustment unit 30 and the codec unit 28 to the audio processing unit 18, where it is analyzed by the adjustment unit 25. The adjustment unit 25 in particular determines, whether the sound (white noise) corresponding to the third speaker signal is still present in the received third microphone signal, or whether it has been blocked/filtered out by the echo canceler 22.

If the sound corresponding to the third speaker signal is still present in the third microphone signal, the gain of the microphone 8 is increased and the procedure is repeated until the third speaker signal is not present in the third microphone signal anymore (step 307).

As a next step 308, the last increment of the microphone gain is revoked, so that the third speaker signal will be present in the third microphone signal again.

As a result, the microphone gain is set to a value which is the maximum value possible without acoustic messages from the service center 15 to the elevator car 2 being blocked by the echo canceler 22.

Alternatively, the method may start with a high microphone gain, in particular a microphone gain which is close to its maximum value, and the microphone gain is gradually reduced until the third speaker signal is detected as being present in the third microphone signal.

Performing a method according to the three sections 100, 200, 300 disclosed in FIG. 2, alone or in combination, results in an optimized adjustment of the parameters of the acoustic elevator communication system 2 allowing for a reliable and convenient acoustic communication between the service center 15 and the elevator car 2 under all operational conditions.

A further enhancement of the acoustic quality can be achieved by adjusting the audio filtering (bass, midrange, treble) for the microphone 8 and/or the speaker 4.

A number of optional features are set out in the following. These features may be realized in particular embodiments, alone or in combination with any of the other features.

In an embodiment, the step (d1) of adjusting the speaker signal such as to eliminate the acoustic resonances in the first microphone signal comprises attenuating specific frequencies in the speaker signal. By attenuating specific frequencies in the speaker signal acoustic resonances may be eliminated very efficiently.

In an embodiment, the step (d1) of adjusting the speaker signal such as to eliminate the acoustic resonances in the first microphone signal is realized by means of an equalizer connected with the speaker and/or with the microphone. An equalizer allows for eliminating acoustic resonances from the first microphone signal very efficiently, in particular by attenuating specific frequencies in the speaker signal.

In an embodiment, the equalizer is a bi-directional equalizer, having a first channel configured for adjusting the speaker signal, and a second channel configured for adjusting the microphone signal. Adjusting both, the speaker signal as well as the microphone signal by means of the respective channels allows for a very efficient elimination of resonances.

In an embodiment, the method further comprises the steps of:
(a2) setting the gain of the speaker to its maximum;
(b2) setting the gain of the microphone to an intermediate value;
(c2) delivering a second speaker signal to the speaker;
(d2) receiving the sound generated by the speaker in response to the second speaker signal with the microphone generating a second microphone signal;
(e2) determining whether the second microphone signal is distorted;
(f2) in case the second microphone signal is distorted, reducing the speaker gain by a predetermined amount; and
(g2) repeating steps (c2) to (f2) until the second microphone signal is not distorted.

Performing these steps allows for setting the gain of the speaker to or at least close to the maximum possible value without causing distortions in the speaker signal. Thus, the gain of the speaker can be set to the optimal or at least close to the optimal value.

In an embodiment, the second speaker signal is a tone signal including a characteristic frequency. Such a tone signal has been found as being very effective for detecting distortions in the speaker signal caused by a too large gain.

In an embodiment, a series of tone signals is generated, each of the tone signals including a characteristic frequency. A series of tone signal has been found as being very effective for detecting distortions in the speaker signal caused by a too large gain.

In an embodiment, the system comprises an echo canceler, which is connected to the output line and to the input line. The echo canceler is configured for preventing echos and/or acoustic feedback from being generated by the acoustic elevator communication system. Such echos and/or acoustic feedback may degenerate or even prevent the communication between the personnel of the service center and passengers residing within the elevator car.

In an embodiment, the method further comprises the steps of:
(a3) providing a third speaker signal in the output line such as to deliver a white noise signal to the speaker via the echo canceler causing the speaker to produce sound;
(b3) delivering a fourth speaker signal simultaneously with the third speaker signal on the output line directly to the speaker, bypassing the echo canceler;
(c3) receiving the sound generated by the speaker within the elevator car with the microphone generating a third microphone signal;
(d3) determining whether the third speaker signal is still present in the received third microphone signal; and
(e3) in case the third speaker signal is still present in the received third microphone signal, increasing the microphone gain and repeating steps a3) to e3);
(f3) in case the third speaker signal is not present in the received third microphone signal, backing-off the microphone gain, in particular to its value before the last increment.

Alternatively, the method further comprises the steps of:
(a3) setting the microphone gain to a high value, in particular to its maximum value;
(b3) providing a third speaker signal in the output line such as to deliver a white noise signal to the speaker via the echo canceler causing the speaker (4) to produce sound;
(c3) delivering a fourth speaker signal simultaneously with the third speaker signal on the output line (6) directly to the speaker bypassing the echo canceler (22);
(d3) receiving the sound generated by the speaker within the elevator car (2) with the microphone generating a third microphone signal;
(e3) determining whether the third speaker signal is present in the received third microphone signal; and
(f3) in case the third speaker signal is not present in the received third microphone signal, backing-off the microphone gain and repeating steps (b3) to (f3).

As a result, the microphone gain is set to or at least close to the maximum value, which is possible without blocking acoustic messages from the service center to the elevator car by the echo canceler.

In an embodiment, the third speaker signal includes a white noise signal. The third speaker signal including or being a white noise signal has been found as being very effective for setting the microphone gain appropriately.

In an embodiment, the fourth speaker signal is a tone signal including a characteristic frequency. Such a tone signal has been found as being very effective for setting the microphone gain appropriately.

In an embodiment, a series of tone signals is generated, each of the tone signal including a characteristic frequency. A series of tone signal has been found as being very effective for setting the microphone gain appropriately.

While the invention has been described with reference to exemplary embodiments, it will be understood by those skilled in the art that various changes may be made and equivalents may be substituted for elements thereof without departing from the scope of the invention. In addition many modifications may be made to adopt a particular situation or material to the teachings of the invention without departing from the essential scope thereof. Therefore, it is intended that the invention not be limited to the particular embodiment disclosed, but that the invention include all embodiments falling within the scope of the claims.

1. A method of adjusting an acoustic elevator communication system (1) comprising a speaker (4) on an output line (6) and a microphone (8) on an input line (10), the speaker (4) and the microphone (8) being installed within an elevator car (2),
the method comprising the steps of:
(a1) delivering a first speaker signal to the speaker (4), the first speaker signal in particular being a white noise signal causing the speaker (4) to produce white noise sound;
(b1) receiving the sound generated by the speaker (4) with the microphone (8) generating a first microphone signal;
(c1) determining acoustic resonances from the first microphone signal; and
(d1) adjusting the speaker signal such as to eliminate the acoustic resonances in the first microphone signal.

2. The method of claim 1, wherein step (d1) comprises attenuating specific frequencies in the speaker signal such as to eliminate resonances in the received microphone signal.

3. The method of claim 1, wherein step (d1) is carried out using an equalizer (20) connected to the speaker (4) and/or to the microphone (8), wherein the equalizer (20) in particular is a bi-directional equalizer (20), having a first channel (20a), which is configured for adjusting the speaker signal, and a second channel (20b), which is configured for adjusting the microphone signal.

4. The method of claim 1, further comprising the steps of:
(a2) setting the gain of the speaker (4) to its maximum;
(b2) setting the gain of the microphone (8) to an intermediate value;
(c2) delivering a second speaker signal to the speaker (4);
(d2) receiving the sound generated by the speaker (4) in response to the second speaker signal with the microphone (8) generating a second microphone signal;
(e2) determining whether the second microphone signal is distorted;
(f2) in case the second microphone signal is distorted, reducing the speaker (4) gain by a predetermined amount; and
(g2) repeating steps (c2) to (f2) until the second microphone signal is not distorted.

5. The method of claim 4, wherein the second speaker signal is a tone signal including a characteristic frequency, wherein the second speaker signal in particular comprises a series of tone signals, each of the tone signals including a characteristic frequency.

6. The method of claim 1, wherein the system (1) comprises an echo canceler (22) connected to the output line (6) and/or to the input line (10), and the method further comprises the steps of:
(a3) providing a third speaker signal in the output line (6) such as to deliver a white noise signal to the speaker (4) via the echo canceler (22) causing the speaker (4) to produce sound;
(b3) delivering a fourth speaker signal simultaneously with the third speaker signal on the output line (6) directly to the speaker (4) bypassing the echo canceler (22);
(c3) receiving the sound generated by the speaker (4) within the elevator car (2) with the microphone (8) generating a third microphone signal;
(d3) determining whether the third speaker signal is still present in the received third microphone signal; and
(e3) in case the third speaker signal is still present in the received third microphone signal, increasing the microphone (8) gain and repeating steps a3) to e3);
(f3) in case the third speaker signal is not present in the received third microphone signal, backing-off the microphone (8) gain.

7. The method of claim 1, wherein the system (1) comprises an echo canceler (22) connected to the output line (6) and/or to the input line (10), and the method further comprises the steps of:
(a3) setting the microphone (8) gain to a high value, in particular to its maximum value;
(b3) providing a third speaker signal in the output line (6) such as to deliver a white noise signal to the speaker (4) via the echo canceler (22) causing the speaker (4) to produce sound;
(c3) delivering a fourth speaker signal simultaneously with the third speaker signal on the output line (6) directly to the speaker (4) bypassing the echo canceler (22);
(d3) receiving the sound generated by the speaker (4) within the elevator car (2) with the microphone (8) generating a third microphone signal;
(e3) determining whether the third speaker signal is present in the received third microphone signal; and
(f3) in case the third speaker signal is not present in the received third microphone signal, backing-off the microphone (8) gain and repeating steps (b3) to (f3).

8. The method of claim 6, wherein the third speaker signal includes a white noise signal, and/or wherein the fourth speaker signal is a tone signal including a characteristic frequency, wherein the fourth speaker signal in particular comprises a series of tone signals, each of the tone signal including a characteristic frequency.

9. The method of claim 1, wherein the method is executed automatically, without human intervention apart from starting the method to be executed.

10. An acoustic elevator communication system (1) comprising:
a speaker (4) on an output line (6) and a microphone (8) on an input line (10), the speaker (4) and the microphone (8) being installed inside an elevator car (2),
a sound generator (24) connected with the output line (6); and
an adjustment unit (25);
wherein the acoustic elevator communication system (1) is configured for:
(A1) driving the sound generator (24) for delivering a first speaker signal to the speaker (4), the first speaker signal in particular being a white noise signal causing the speaker (4) to produce white noise sound;
(B1) receiving the sound generated by the speaker (4) with the microphone (8) generating a first microphone signal;
(C1) determining acoustic resonances from the first microphone signal; and
(D1) adjusting the speaker signal such as to eliminate the acoustic resonances in the first microphone signal.

11. The acoustic elevator communication system (1) of claim 10 further comprising an equalizer (20) connected with the output line (6) and/or with the input line (10) and wherein the adjustment unit (25) is configured for adjusting the equalizer (20) for adjusting the speaker signal.

12. The acoustic elevator communication system (1) of claim 11, wherein the equalizer (20) is a bi-directional equalizer (20), in particular with a first channel, which is configured for adjusting the speaker signal, and a second channel, which is configured for adjusting the microphone signal.

13. The acoustic elevator communication system (1) of claim 10, wherein the adjustment unit (25) is further configured for
(A2) setting the gain of the speaker (4) to its maximum;
(B2) setting the gain of the microphone (8) to an intermediate value;
(C2) delivering a second speaker signal to the speaker (4);
(D2) receiving the sound generated by the speaker (4) in response to the second speaker signal with the microphone (8) generating a second microphone signal;
(E2) determining whether the second microphone signal is distorted; and
(F2) in case the second microphone signal is distorted, reducing the speaker (4) gain by a predetermined amount;
(G2) repeating steps (C2) to (F2) until the second microphone signal is not distorted.

14. The acoustic elevator communication system (1) of claim 13, wherein the second speaker signal is a tone signal including a characteristic frequency, wherein the second speaker signal in particular comprises a series of tone signals, each of the tone signal including a characteristic frequency.

15. The acoustic elevator communication system (1) of claim 10, wherein the sound generator is a first sound generator (24) and the system (1) further comprises an echo canceler (22) and a second sound generator (26) connected upstream of the echo canceler (22), and
wherein the adjustment unit (25) is further configured for
(A3) providing a third speaker signal in the output line (6) such as to deliver a white noise signal to the speaker (4) via the echo canceler (22) causing the speaker (4) to produce sound;
(B3) delivering a fourth speaker signal simultaneously with the third speaker signal on the output line (6) directly to the speaker (4) bypassing the echo canceler (22);
(C3) receiving the sound generated by the speaker (4) within the elevator car (2) with the microphone (8) generating a third microphone signal;
(D3) determining whether the third speaker signal is still present in the received third microphone signal; and
(E3) in case the third speaker signal is still present in the received third microphone signal, increasing the microphone (8) gain and repeating steps (A3) to (E3);
F3) in case the third speaker signal is not present in the received third microphone signal, backing-off the microphone (8) gain.

16. The acoustic elevator communication system (1) of claim 10, wherein the sound generator is a first sound generator (24) and the system (1) further comprises an echo canceler (22) and a second sound generator (26) connected upstream of the echo canceler (22), and wherein the adjustment unit (25) is further configured for
(A3) setting the microphone (8) gain to a high value, in particular to its maximum value;
(B3) providing a third speaker signal in the output line (6) such as to deliver a white noise signal to the speaker (4) via the echo canceler (22) causing the speaker (4) to produce sound;
(C3) delivering a fourth speaker signal simultaneously with the third speaker signal on the output line (6) directly to the speaker (4) bypassing the echo canceler (22);
(D3) receiving the sound generated by the speaker (4) within the elevator car (2) with the microphone (8) generating a third microphone signal;
(E3) determining whether the third speaker signal is present in the received third microphone signal; and
(F3) in case the third speaker signal is not present in the received third microphone signal, backing-off the microphone (8) gain and repeating steps (B3) to (F3).

17. The acoustic elevator communication system (1) of claim 15, wherein the third speaker signal includes a white noise signal and/or wherein the fourth speaker signal is a tone signal including a characteristic frequency, wherein the fourth speaker signal in particular comprises a series of tone signals, each of the tone signal including a characteristic frequency.
